(19) United States
(12) Patent Application Publication
(10) Pub. No.: US 2026/0237593 A1
(43) Pub. Date: Aug. 13, 2026

(54) Charged-Particle Beam Device

(71) Applicant: Hitachi High-Tech Corporation, Minato-ku, Tokyo (JP)

(72) Inventor: Daisuke HIRANO, Tokyo (JP)

(21) Appl. No.: 19/155,277

(22) PCT Filed: Mar. 9, 2023
(86) PCT No.: PCT/JP2023/009147

§ 371 Date: Aug. 11, 2025

(51) Int. Cl. H01J 37/22; H01J 37/244; H01J 37/28

(52) U.S. Cl. CPC H01J 37/226; H01J 37/222; H01J 37/244; H01J 37/28; H01J 2237/2448; H01J 2237/2817

(57) ABSTRACT

The purpose of the present invention is to provide a charged-particle beam device capable of quickly identifying a defect position in an observed image of a sample to improve inspection throughput. The charged-particle beam device according to the present invention comprises a database describing such combinations of wavelengths and polarization directions of light that the contrast in an observed image of a defect that a sample has can be enhanced, wherein: the sample is irradiated with the light using at least one of the combinations; the observed image is generated for each of the combinations; and the defect is detected using the observed image (see FIG. 7).

### TECHNICAL FIELD

The present invention relates to a charged-particle beam device.

### BACKGROUND ART

A scanning electron microscope (SEM) is used for measuring and inspecting a fine pattern of a semiconductor device. The SEM detects secondary electrons emitted from a sample, and therefore, contrast of an SEM image reflects an electron state and a shape of the sample.

The defect review SEM is an application device of a scanning electron microscope (SEM). A defect review SEM is used to convert a defect detected by a semiconductor wafer defect inspection device into information on an image with a high magnification at which the defect can be recognized using the SEM. Therefore, the defect review SEM is mainly used together with an inspection device in a manufacturing line of an electronic device such as a semiconductor. The wafer defect inspection device detects a defect, lists defect position coordinates as defect information, and outputs the defect information as a file. The inspected wafer and the inspection result file are loaded into the defect review SEM. The review SEM imports a file in which an inspected wafer and an inspection result thereof (defect position coordinate information) are described. The review SEM specifies accurate coordinates of defects based on the position information in the file of the defect list (positioning). The review SEM takes and stores a photograph of the defect.

PTL 1 discloses an optically assisted SEM that acquires a material and a structural distribution of a sample as an image having a resolution in nanometer units from a change in a state of electrons in the sample caused by applying illumination light to the sample while the sample is irradiated with an electron beam. PTL 2 discloses a technique of increasing the contrast of a pattern shape of a sample by controlling the polarization and wavelength of light to be emitted as a method for improving the visibility of the SEM. NPLs 1 and 2 will be described below.

### CITATION LIST

### Patent Literature

PTL 1: WO2020/194575
PTL 2: WO2020/053967

### Non Patent Literature

NPL 1: Zhaogang Dong et al. “Ultraviolet Interband Plasmonics with Si nanostructures”, Nano Letters, September 2019
NPL 2: Quan Sun et al. “Direct imaging of the near field and dynamics of surface plasmon resonance on gold nanostructures using photoemission electron microscopy”, Light: Science & Applications, December 2013

### SUMMARY OF INVENTION

### Technical Problem

Even if a center of the field of view of the defect review SEM is set to the position coordinates described in the file of the defect list, there may be no defect in the field of view. In this case, a defect is present outside the field of view, and therefore, it is required to widen the field of view. A spatial resolution and the field of view are in a trade-off relationship, and thus, when a spatial size of the defect is small, the defect may not be found even if the field of view is widened. Therefore, in order to find the defect, it is required to find the defect in a narrow field of view, which increases search time. Therefore, a technique capable of quickly specifying a defect position in a captured image of a sample is desired.

PTLs 1 and 2 describe a technique of increasing the contrast of the image of the pattern shape of a sample. It is considered that a defect shape or the like can be identified by visually recognizing an observation image with increased contrast. On the other hand, as a premise of visually recognizing the defect image, it is required to specify the defect position in the observation image in advance (further, increase the observation magnification of the specified defect position as necessary). That is, the defect position detection and the defect observation are separate processes from each other, and thus, another consideration is required to quickly specify the defect position even when a technique capable of clearly visually recognizing a sample image is provided as in PTLs 1 and 2.

In order to quickly specify the defect position, for example, it is desirable to automatically identify the defect position in the observation image by a device. The technique described in PTLs 1 and 2 has room for further examination of a specific method for quickly specifying a defect position in an observation image with increased contrast.

The invention has been made in view of the above problems, and an object thereof is to provide a charged-particle beam device capable of quickly identifying a defect position in an observation image of a sample to improve inspection throughput.

### Solution to Problem

A charged-particle beam device according to the invention includes a database that describes combinations of a wavelength of light and a polarization direction of the light, which enhance contrast of an observation image of a defect in a sample. The light is emitted to the sample using at least one of the combinations, the observation image is generated for each of the combinations, and the defect is detected using the observation image.

### Advantageous Effects of Invention

According to the charged-particle beam device of the invention, a defect position in an observation image of the sample can be quickly specified to increase the inspection throughput.

Other problems, configurations, advantages, and the like of the invention will become apparent from the following description of embodiments.

### BRIEF DESCRIPTION OF DRAWINGS

FIG. 1 is a conceptual diagram of a field enhancement factor for each of horizontal polarization and vertical polarization.

FIG. 2 is a typical conceptual diagram showing σpixel with respect to an SEM spatial resolution.

FIG. 3 shows LSPR characteristics of a pattern having a normal size and a pattern having a size abnormality.

FIG. 4 shows a typical example of an SEM image of a defective pattern having the characteristics shown in FIG. 1.

FIG. 5 is a configuration diagram of a charged-particle beam device 1 according to Embodiment 1.

FIG. 6 shows an example of a GUI of an optically assisted defect review SEM.

FIG. 7 is a flowchart showing an operation of the charged-particle beam device 1.

FIG. 8 shows an SEM image of a hole pattern when light is off.

FIG. 9 shows an SEM image when a wavelength non-resonant with the LSPR induced in a hole shape is used for illumination light.

FIG. 10 shows an SEM image when a wavelength resonant with the LSPR induced in the hole shape is used for illumination light.

FIG. 11 shows an SEM image when a wavelength resonant with the LSPR induced in the hole shape is used for illumination light.

FIG. 12 shows a procedure for examining a condition for maximizing CNR represented by the formula (3).

FIG. 13 shows an inspection image of a hot spot where pattern breakage defects frequently occur.

FIG. 14 shows that CNR can be increased by difference processing of an optically assisted SEM image.

FIG. 15 shows a high-resolution SEM image of a circuit pattern including a pattern line width narrowing portion.

FIG. 16 shows an optically assisted SEM image of a pattern circuit in FIG. 15.

### DESCRIPTION OF EMBODIMENTS

### Principle of Invention

The principle of the invention will be described below prior to the description of embodiments of the invention. First, a method of finding a small defect in a wide field of view will be described. A review SEM detects a defect from a captured image. A shape or a material characterizing the defect generates contrast of a defect image, and therefore, a spatial resolution of an SEM is required to be sufficiently smaller than a defect size in order to find the defect. On the other hand, the field of view and the spatial resolution are in a trade-off relationship, and thus, the spatial resolution decreases, and the defect shape cannot be recognized when the field of view is widened. That is, the field of view is limited by a spatial size of the defect shape. From the above description, in order to find a small defect in a wide field of view, a method of detecting a defect with a characteristic other than a shape needs to be established.

The invention utilizes the fact that the wavelength characteristics of the localized surface plasmon resonance (LSPR) are sensitive to a change in the shape of a nanometer size. For example, the LSPR generated in a patterned sample is considered. The wavelength characteristic of the LSPR changes when a pattern shape locally changes due to the structural defect, and therefore, the field enhancement factor can be changed at the defect position by irradiating the sample with light having a wavelength resonating with the pattern as illumination light. The enhanced electric field increases an intensity of the secondary electrons through excited carriers, and therefore, a signal intensity locally changes at the defect position. In order to identify a defect in a pattern by using a local change in signal intensity, it is required that a change in the signal intensity at the defect position is sufficiently larger than background signal noise. Therefore, the contrast between a signal derived from the defect and a background signal can be improved, and the defect can be detected in a wide field of view by optimizing the spatial resolution of the design pattern so as to minimize the background signal noise.

Next, a method of classifying small defects in a wide field of view will be described. Up to now, defects have been classified according to signal shapes thereof and the like. When the spatial resolution is increased to such an extent that the shape characterizing the defect cannot be recognized, the defect cannot be classified according to the shape. Therefore, as a unit for classifying defects, the fact that the LSPR has wavelength characteristics and polarization anisotropy is utilized. For example, the LSPR generated in a patterned sample in which holes are regularly arranged two-dimensionally is considered. In the present description, polarization is considered only in the in-plane direction of the sample. When adjacent holes are connected by structural defects and polarization parallel to the connecting direction is compared with polarization perpendicular thereto, anisotropy appears in the wavelength characteristics of the LSPR. Therefore, the defect anisotropy can be classified by comparing defect signals under illuminations of the polarizations perpendicular to each other.

Details of the operation principle of the invention will be described. Excited electrons near the Fermi surface generated by irradiating the sample with light increase an amount of secondary electrons emitted by electron beam excitation. When it is assumed that an emission amount of secondary electrons per pulse of the electron beam under pulsed light irradiation is proportional to an amount of light energy absorbed by the sample, the formula (1) is obtained. S(x, y) is an amplification amount of secondary electrons emitted by light irradiation at a position (x, y) on the sample surface. εₘₐₜₑᵣᵢₐₗ represents a dielectric constant of the sample. ε₀ represents the dielectric constant of the background, and corresponds to vacuum here. E represents an electric field intensity. The escape length of the secondary electrons is represented by D. T represents the pulse width of the pulsed light and is sufficiently shorter than the lifetime t_{decay} of the excited electrons. t_{delay} represents a difference in sample incidence time between a light pulse and an electron beam pulse. Iₚ represents an irradiation charge of an electron beam. The normal direction of a sample surface was set to be Z, and the interface with vacuum was set to be z=0.

$$\begin{matrix}[ Math . 1 ] & \\ S ( x , y ) ∝ {I}_{p} exp ( \frac{- {t}_{delay}}{{t}_{decay}} ) {\int }_{0}^{∞} {\int }_{0}^{T} ( {ε}_{material} - {ε}_{0} ) \frac{\partial E ( t , x , y , z )}{\partial t} \cdot E ( t , x , y , z ) \cdot exp ( - \frac{z}{D} ) dtdz & ( 1 )\end{matrix}$$

In a wavelength region in which a real part of the dielectric constant is negative, it has been reported that the LSPR occurs due to a structure with a nanometer size (NPL 1). Such electron excitation caused by local electric field enhancement is found as enhancement of an intensity in a photoelectron emission image (NPL 2). From this, it is expected that an SEM image reflecting an excited electron distribution enhanced by the LSPR can be acquired by light irradiation.

An SEM signal sₚᵢₓₑₗ per pixel during light irradiation can be described by the formula (2). However, an integration range is limited to a pixel range of interest.

$$\begin{matrix}[ Math . 2 ] & \\ {s}_{pixel} = \int \int S ( x , y ) dxdy & ( 2 )\end{matrix}$$

When the intensity per pixel of the patterned sample is set to be sₚᵢₓₑₗ^{pattern}, the intensity of the pixel including the defect is set to be sₚᵢₓₑₗ^{defect}, and the amount of noise per pixel is set to be σₚᵢₓₑₗ, it is required to increase a contrast-to-noise ratio (CNR) of a defect signal represented by the formula (3) as much as possible in order to detect the defect from the signal contrast in a wide field of view.

$$\begin{matrix}[ Math . 3 ] & \\ CNR = \frac{\vert {s}_{pixel}^{pattern} - {s}_{pixel}^{defect} \vert}{{σ}_{pixel}} & ( 3 )\end{matrix}$$

### (Aspect 1 of Principle for Increasing CNR: Polarization Direction)

The fact that the numerator on the right side of the formula (3) can be maximized by selecting a wavelength and a polarization direction of the illumination light will be described. The LSPR is sensitive to a nanometer size shape, and therefore, a wavelength characteristic of the LSPR changes when a pattern shape changes due to a structural defect. A case where in a pattern shape having the resonance peaks of λ₀^{←→} and λ₀^{↓↑} for the horizontal polarization and the vertical polarization, respectively, the resonance peak is changed from λ₀^{←→} to λ₁^{←→} and changed from λ₀^{↓↑} to λ₁^{↓↑} due to the structural defect is considered. However, the horizontal polarization is an axial direction characterizing the periodicity or structure of the pattern, and the vertical direction is a component perpendicular to the horizontal polarization in the in-plane direction of the pattern.

FIG. 1 is a conceptual diagram of a field enhancement factor for each of horizontal polarization and vertical polarization. When the polarization of the illumination is set to be horizontal and the wavelength is set to be λ₀^{←→}, the electric field enhancement is maximized on the pattern, but the electric field enhancement is hardly performed at the defect position. When the polarization of illumination is set to be vertical and the wavelength is set to be λ₀^{↓↑}, the enhancement degree hardly changes between the pattern position and the defect position. Therefore, in a defective pattern having such wavelength characteristics, it can be seen that the numerator on the right side of the formula (3) can be maximized by setting the polarization to be horizontal and the wavelength to be ₀^{←→}.

### (Aspect 2 of Principle for Increasing CNR: Spatial Resolution and Pattern Pitch)

The fact that the denominator on the right side of the formula (3) can be minimized by optimizing the spatial resolution of the SEM will be described. When σₚᵢₓₑₗ is defined as a standard deviation of a signal intensity sₚᵢₓₑₗ^{pattern} in the normal portion of the patterned sample, σₚᵢₓₑₗ is expressed as follows using a term due to the shape of the sample and a term due to the discreteness of electrons.

$$\begin{matrix}[ Math . 4 ] & \\ {σ}_{pixel} = \sqrt{{σ}_{struct}^{2} + {σ}_{rand}^{2}} & ( 4 )\end{matrix}$$

The fact that the formula (4) can be minimized, that is, the CNR can be maximized by appropriately setting the SEM spatial resolution or the pixel size will be described. Hereinafter, a patterned sample having periodic patterns in directions perpendicular to each other and having the matching pattern pitch in each direction will be considered. σ_{struct} represents a signal variation between pixels caused by the sample pattern, and therefore, σ_{struct} is maximized when the SEM spatial resolution or the pixel size is sufficiently smaller than the spatial scale characterizing the pattern, and is minimized when approaching the pattern pitch.

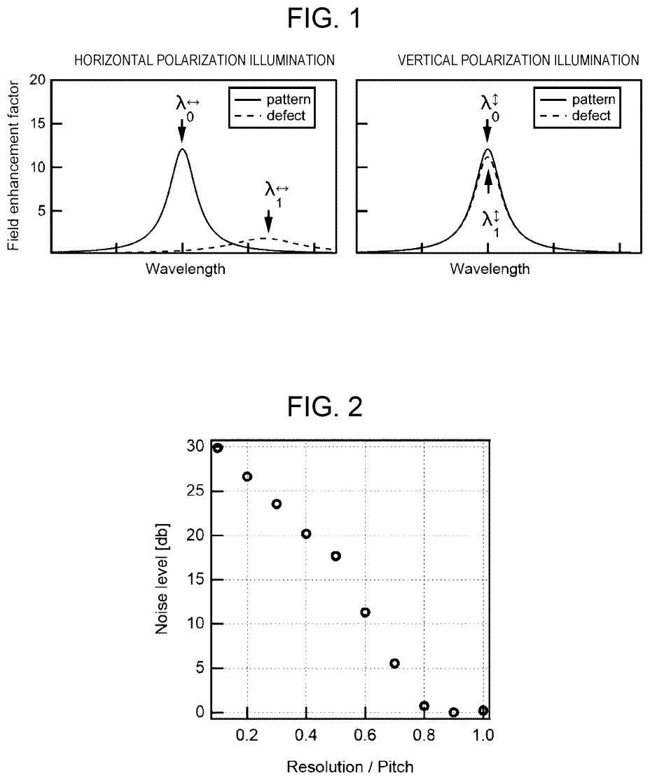

FIG. 2 is a typical conceptual diagram showing σₚᵢₓₑₗ with respect to an SEM spatial resolution. It can be seen that the noise monotonously decreases with respect to the increase in the resolution and becomes the minimum near the pattern pitch. The noise level can be minimized by selecting an appropriate spatial resolution and an appropriate pixel size for the design pattern.

### (Aspect 3 of Principle for Increasing CNR: Difference Image)

The fact that the first term on the right side of the formula (4) can be minimized by using a signal from a normal pattern as a background will be described. Die-to-die inspection for comparing patterns between dies is considered. The LSPR characteristics in the normal pattern are the same between different dies, and thus, the signal intensity σ_{struct} in the normal portion is canceled by generating a difference image between different dies. That is, σ_{struct} of (4) can be minimized. This method corresponds to the minimization of the standard deviation of the signal intensity in the normal portion of the sample. It can be considered that a defect image remains and the contrast of the defect image is enhanced by obtaining a difference between observation images in the same normal portion of different dies.

A method of inspecting a dimensional abnormality of a pattern using the fact that the optically assisted SEM signal intensity has a light wavelength characteristic will be described. An example is considered in which the peak wavelength of the field enhancement factor by the LSPR shifts to a short wavelength when an abnormality occurs in the pattern dimension.

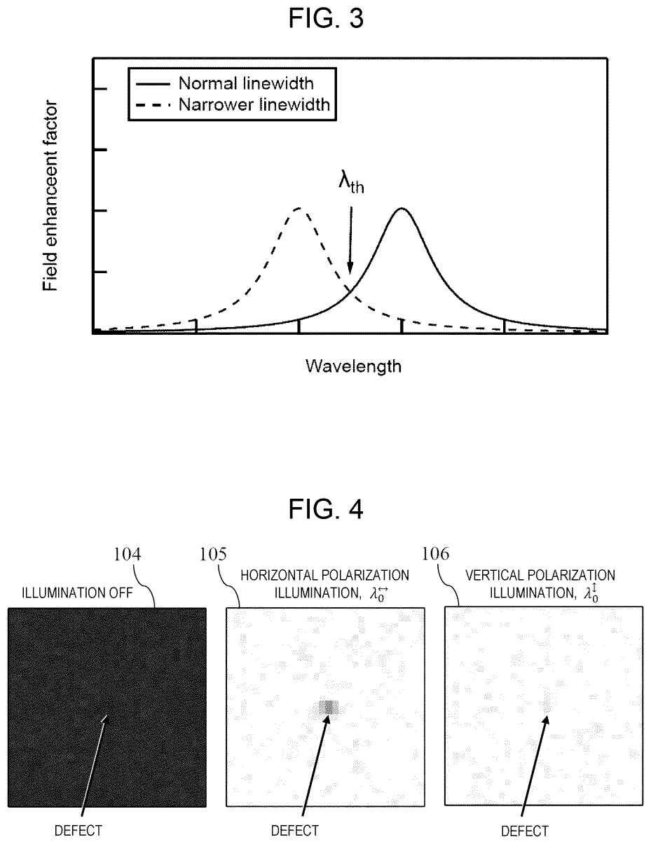

FIG. 3 shows an LSPR characteristic of each of a pattern having a normal size and a pattern having size abnormality. The LSPR characteristic of the normal portion in which a pattern dimension is a design median value is indicated by a straight line, and the LSPR characteristic of the abnormal portion in which the dimension is regarded to be abnormal due to narrowing is indicated by a dotted line. A wavelength at which the LSPR field enhancement factors of the normal portion and the abnormal portion are equal to each other is set to be λth. The field enhancement factor of the normal portion is larger than the field enhancement factor of the dimensionally abnormal portion at an incident light wavelength λ>λth, and the field enhancement factor of the normal portion is smaller than the field enhancement factor of the dimensionally abnormal portion at an incident light wavelength λ<λth. The pattern dimensional abnormality can be grasped as a change in the field enhancement factor of the LSPR by comparing the optically assisted SEM signal intensities of the long and short wavelengths based on λth.

### Embodiment 1

FIG. 4 shows a typical example of an SEM image of a defective pattern having the characteristics shown in FIG. 1. A pixel size of the SEM image was set to the same value as the pattern pitch. The defect is located at a center of the field of view. The reference numeral 104 denotes an SEM image without illumination light, the reference numeral 105 denotes an SEM image when the polarization of illumination is set to be horizontal and a wavelength is set to be λ₀^{←→}, and the reference numeral 106 denotes an SEM image when the polarization of illumination is set to be vertical and the wavelength is set to be λ₀^{↓↑}. The image contrast corresponds to the signal intensity. The signal intensity in black is the weakest, and the signal intensity in white is the strongest.

The images 105 and 106 are much brighter than the image 104. This is because the illumination increases secondary electrons derived from the pattern shape. Focusing on the defect position in the image 104, the defect cannot be found because the resolution of the SEM is lower than that of the defect shape. In the image 105, a defect can be found to have a decrease in signal intensity. Focusing on the defect position in the image 106, the defect cannot be recognized because the signal intensity is the same as that of the pattern signal. As described above, in the defective pattern having the wavelength characteristic shown in FIG. 1, the formula (3) is maximized by setting the polarization to be horizontal and the wavelength to be λ₀^{←→}, and thus, it can be seen that the defect can be inspected from the contrast of the signal intensity even if the resolution of the SEM is low.

The polarization and wavelength characteristics of the LSPR generated in the pattern depend on the material, shape, size, arrangement direction, pitch, and uneven duty ratio of the pattern portion. Further, the polarization and wavelength characteristics of the LSPR generated in the shape defect are determined by an element that changes the pattern shape. For example, a recess is filled, a protrusion is removed, or a shape change direction is used. Therefore, in order to inspect a defect by maximizing the formula (3), it is required to set a plurality of sets of polarization and wavelength according to the material and pattern of the wafer read into the device and the type of defect to be inspected. It takes a very long time to search for such parameters for each read wafer, and the inspection throughput is significantly reduced. In order to improve the throughput of the defect inspection, it is required to classify conceivable patterns, materials, shapes, and defects generated therein, calculate or experimentally examine the LSPR characteristics for each classification, and prepare a wavelength and polarization database that maximizes the formula (3). A procedure for preparing such a database will be described below.

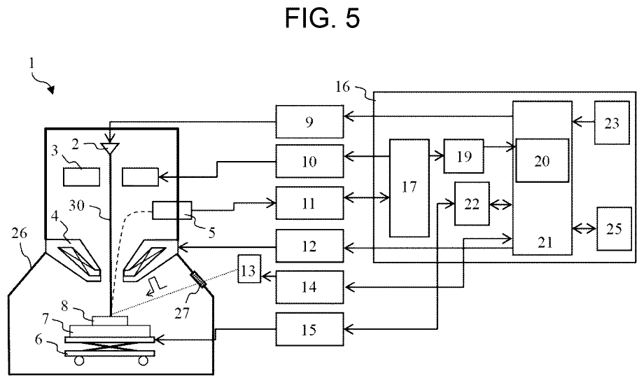

FIG. 5 is a configuration diagram of a charged-particle beam device 1 according to Embodiment 1. The charged-particle beam device 1 is implemented as a defect review SEM. The charged-particle beam device 1 is implemented as a scanning electron microscope that acquires an observation image of a sample 8 by emitting an electron beam 30 (primary charged particles) to the sample 8. The charged-particle beam device 1 includes an electron optical system, a stage mechanism system, an electron beam control system, a light irradiation system, and a main console 16 (computer).

The electron optical system includes an electron gun 2, a deflector 3, an electron lens 4, and a detector 5. The stage mechanism system includes an XYZ stage 6 and a sample holder 7. The electron beam control system includes an electron gun control unit 9, a deflection signal control unit 10, a detection control unit 11, and an electron lens control unit 12. The stage control system includes a stage driver 15 and a stage position command unit 22. The light irradiation system includes a light source 13, a light control unit 14, and a glass window 27. The main console 16 further includes an image forming system and a data input and output system. The image forming system includes an image processing unit 17 having a detection sampling function synchronized with an optical signal, and an image signal processing unit 19. The data input and output system includes an input setting unit 21 for imaging conditions of the electron beam 30, a human interface 20, an external data input and output unit 25, and a defect database 23.

The electron beam 30 accelerated by the electron gun 2 is focused by the electron lens 4 and is emitted to the sample 8. The deflector 3 controls an irradiation position of the electron beam 30 on the sample 8. A position of the sample 8 is controlled by the XYZ stage 6. The main console 16 controls the XYZ stage 6 via the stage driver 15. The detector 5 detects emitted electrons (secondary charged particles) emitted from the sample 8 by irradiating the sample 8 with the electron beam 30. The input setting unit 21 is a functional unit for a user to designate and input an acceleration voltage, an irradiation current, a deflection condition, a detection sampling condition, an electron lens condition, an XYZ stage position, and the like.

The light source 13 emits light with which the sample 8 is irradiated. The light source 13 is a laser capable of outputting various spectrum in an output wavelength range from ultraviolet rays to near-infrared rays, and can change parameters such as a polarization plane, light intensity, spectrum, output timing, and pulse width. The light emitted from the light source 13 is emitted to the sample 8 placed in a vacuum through the glass window 27 provided in a device housing 26. The light source 13 can include, for example, a wavelength conversion unit/polarization control unit/intensity control unit. The wavelength conversion unit is a component capable of changing a light spectrum, and examples thereof include wavelength conversion using a light parametric amplifier, whitening by self-phase modulation using an optical fiber, and line width narrowing and spectrum shaping using an optical filter. The polarization control unit is a component capable of changing a polarization plane of light, and examples thereof include a wire grid type and a crystal type using a birefringence phenomenon of a material itself. The intensity control unit can control the light intensity by, for example, a combination of a wavelength plate and a polarization beam splitter. The light control unit 14 controls parameters of light emitted by the light source 13, which represent physical characteristics. The user designates the light parameter for the light control unit 14 via the input setting unit 21.

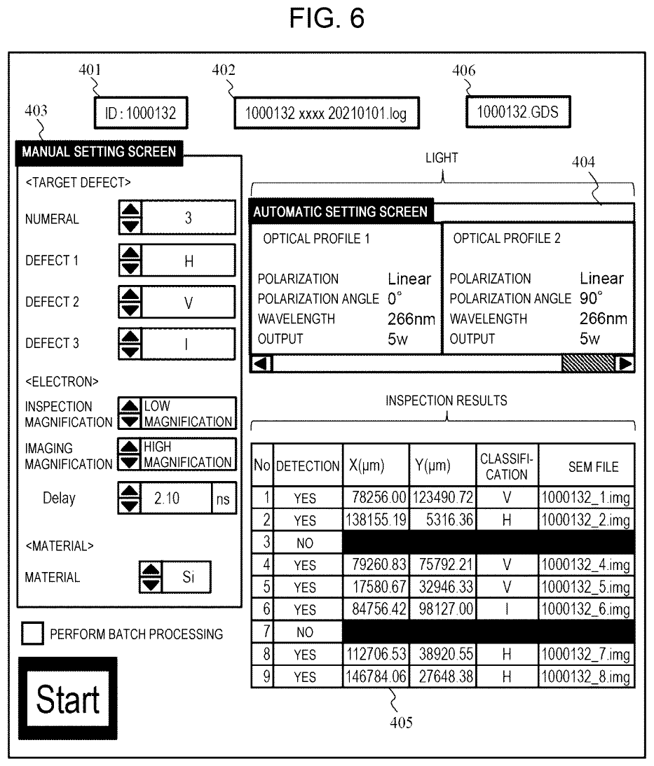

FIG. 6 shows an example of a GUI of an optically assisted defect review SEM. The charged-particle beam device 1 performs inspection using, as an input, the defect position on the wafer, which is described in the defect list output from the defect inspection device, and outputs the result. 401 denotes an ID of a read wafer. 402 denotes a name of a file in which a defect list input from the outside is written. The reference numeral 406 denotes a design pattern of the wafer input from the outside. 403 displays an item set by the user is displayed. In the item of the target defect, what kind of defect is to be inspected is designated, and here, as an example, three types of defects including H, I, and V are set as inspection items. The type and the number can be changed by the user. Parameters of the electron gun 2 are set in the electron term. Examples of the setting items include an enlargement magnification during defect inspection, an enlargement magnification during image capturing, and a Delay that determines an emission timing of an electron gun with respect to a trigger. 404 displays a light setting item. 404 is automatically determined by the main console 16 according to the material, the design pattern, and the inspection defect in accordance with the contents of the defect database 23. The profile of the light parameters is created by the number necessary for classifying all the designated target defects. In the optical profile, the amount characterizing the illumination is displayed, and as an example, a type of polarization, an angle of a main axis of polarization, a center wavelength, and an output are set. An example of an inspection result is displayed in a table 405. The No column indicates the number of the defect described in the defect list in 402. The detection column indicates whether a defect has been detected near the coordinates associated with the number, and further indicates the detected coordinates (X, Y) on the wafer when a defect has been detected. The classification column indicates which of the targets set in 403 the detected defect corresponds to. The SEM file column indicates file names of SEM images captured at the coordinates (X, Y).

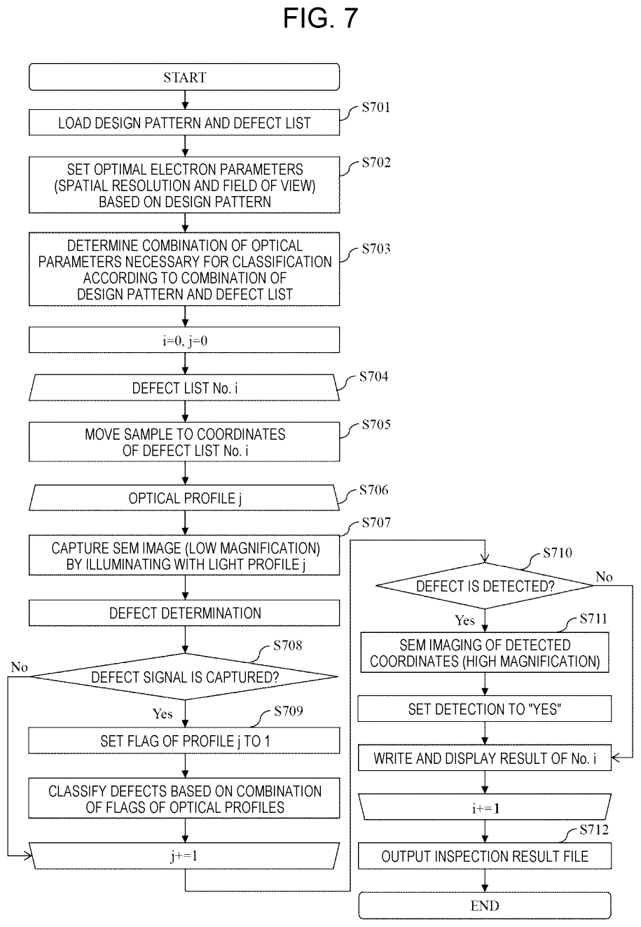

FIG. 7 is an operation flowchart of the charged-particle beam device 1. Each step in FIG. 7 will be described below.

### (FIG. 7: Steps S701 to S702)

The main console 16 reads a design pattern (406 in FIG. 6) of the sample 8 and a defect list (402 in FIG. 6) listing defect types and defect positions output by the defect inspection device (S701). The design pattern includes information on design values such as the type, size, and number of shape patterns. The main console 16 sets optimum electronic parameters (spatial resolution and field of view) based on the design pattern (S702).

### (FIG. 7: Step S703)

The main console 16 determines a combination of light irradiation parameters (optical profiles) necessary for classifying defects according to the combinations of the design pattern and the defect list. The combination is determined with reference to the defect database 23. The defect database 23 describes, for each of the combinations of the design pattern and the defect type, a candidate (one or more) of an optical profile suitable for detecting the defect type. In the target defect column of FIG. 6, a defect type designated as a detection target by the user among defect types described in the defect list can be input. Based on the designated defect type, the main console 16 determines an optical profile according to the correspondence relationship between the defect type and the optical profile described in the defect database 23. Details of the defect database 23 will be described below.

### (FIG. 7: Steps S704 and S705)

The main console 16 repeats the following steps S705 to S711 by the number of defects described in the defect list (S704). The main console 16 moves the sample 8 to a coordinate of a defect list No. i (S705).

### (FIG. 7: Step S706)

The main console 16 repeats the following steps S707 to S709 by the number of optical profiles determined in S703.

### (FIG. 7: Step S707)

The main console 16 illuminates the sample 8 using an optical profile j and captures an SEM image having a low magnification lower than that of a high magnification SEM image to be described below. The main console 16 determines whether the captured SEM image includes a defect. A specific example of the determination method will be described below together with a specific example of the observation image.

### (FIG. 7: Step S707: Supplement)

The main console 16 may search for a defect in the defect coordinates and a periphery thereof described in the defect list. In S707, an image having a low magnification lower than that of S711 is used, and therefore, it is possible to efficiently search for a defect using a wide field of view.

### (FIG. 7: Steps S708 and S709)

If the observation image includes a defect (S708: Yes), the main console 16 sets, for the optical profile j, a flag indicating that defect detection has been performed (for example, sets a value of the flag to 1) (S709). The main console 16 classifies the defect type based on the combination of flags of the optical profile j. If the observation image does not include a defect (S708: No), the processing returns to S706 and the same processing is repeated for the next optical profile (j is incremented by one).

### (FIG. 7: Steps S710 to S712)

For the optical profile in which the defect is detected (S710: Yes), the main console 16 captures a high magnification SEM image at the coordinates at which the defect is detected (S711). The main console 16 records the result of the defect detection in an inspection result file (a data file describing the content of the inspection result 405). The result of defect detection is also recorded for the optical profile in which no defect is detected (S710: No). The main console 16 outputs the inspection result file created as described above to an appropriate storage device.

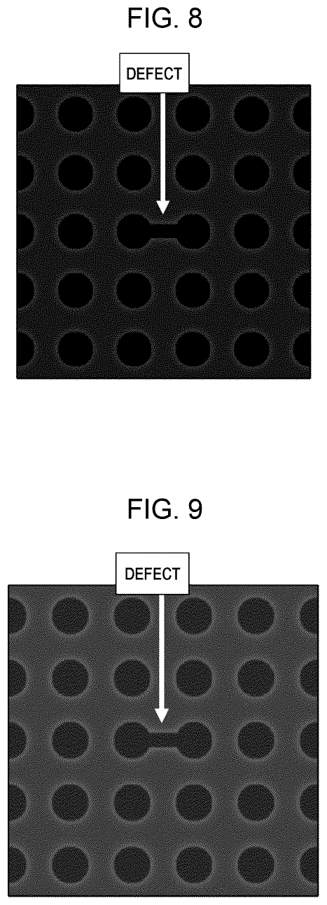

FIG. 8 shows an SEM image of a hole pattern when the light is off. The magnification of the SEM image is a high magnification. A defect in which two laterally arranged holes are connected can be found at a center of the image. The defect database 23 describes light parameters that maximize signal contrast between such a defect portion and a normal hole pattern portion. In order to construct the defect database 23, for example, it is conceivable to specify an optical profile capable of satisfactorily observing a defect by acquiring an observation image of the defect using various optical profiles. The example will be described with reference to FIGS. 9 to 11.

FIG. 9 shows an SEM image when a wavelength non-resonant with the LSPR induced in the hole shape is used for the illumination light. It can be seen that the whole image is brighter than that in FIG. 8. This is because the amount of secondary electrons emitted from the entire wafer is increased by photoexcitation. However, the LSPR does not resonate with the hole shape, and therefore, the contrast is not sufficient for both the defect portion and the normal hole pattern. Therefore, it can be seen that the wavelength at this time is not suitable for detecting the defect in FIG. 9.

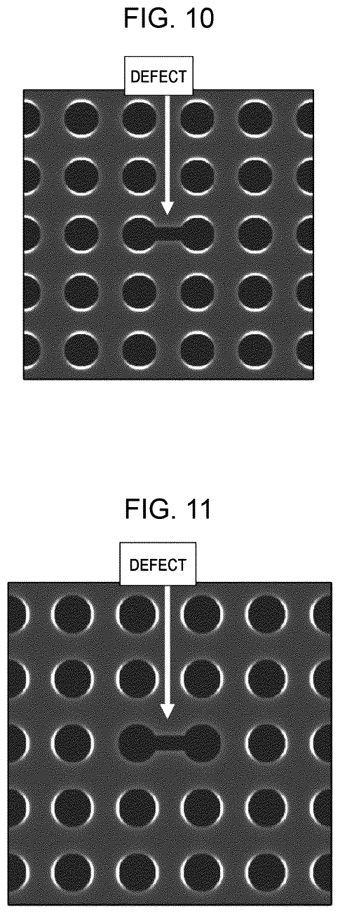

FIG. 10 shows an SEM image when a wavelength resonating with the LSPR induced in the hole shape is used for illumination light. The incident polarization is vertical polarization. In both the defect portion and the normal hole pattern portion, local signal enhancement can be found at an end portion of the pattern.

FIG. 11 shows an SEM image when a wavelength resonant with the LSPR induced in the hole shape is used for illumination light. The incident polarization is horizontal polarization. In a normal hole pattern portion, local signal enhancement can be found at a pattern end portion, but local signal enhancement cannot be found in a defect portion.

By comparing FIG. 10 with FIG. 11, a defect (here, a defect connecting the holes) whose contrast is enhanced with respect to the vertical polarization can be detected. Further, a direction in which the defect extends (here, a left-right direction in the drawing) can be detected. For example, a defect image in which the position and direction of a defect connecting the holes are enhanced can be obtained by generating a difference image between FIGS. 10 and 11. A specific example will be described below.

As illustrated in FIGS. 9 to 11, the optical profile capable of enhancing the defect contrast on the observation image for each defect type can be specified by generating the observation image while variously changing the combination of the wavelength and the polarization direction capable of enhancing the defect. The defect database 23 records the optical profile and the defect type in association with each other. The correspondence relationship can be recorded for each design pattern (hole pattern in FIGS. 8 to 11). Therefore, in S703, the optical profile candidates suitable for detecting the defect can be selected based on the combination of the design pattern and the defect list.

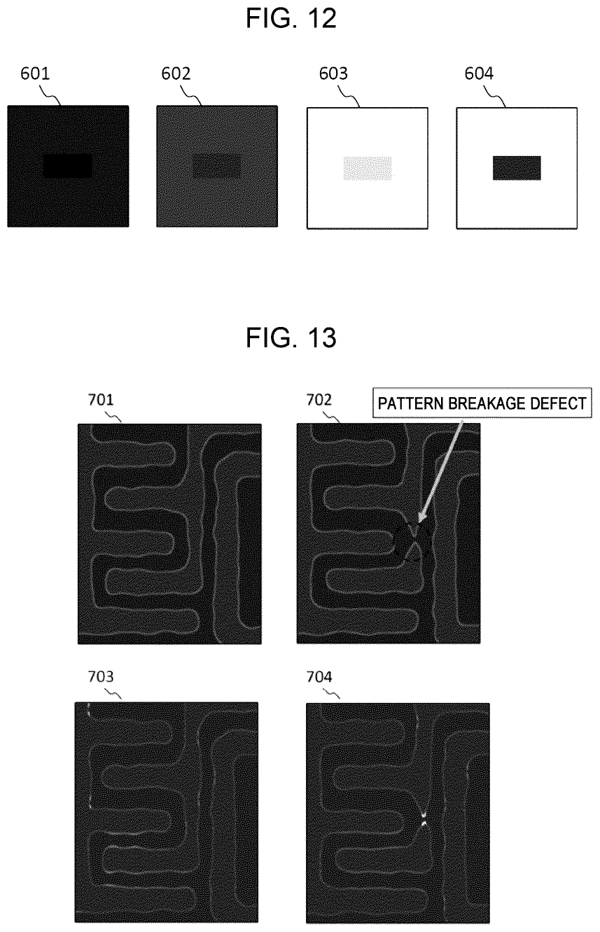

FIG. 12 shows a procedure for examining a condition for maximizing the CNR represented by the formula (3). FIG. 8, FIG. 9, FIG. 10, and FIG. 11 were divided and integrated for each pattern pitch, and the in-plane distribution of sₚᵢₓₑₗ was evaluated. FIG. 12 is an in-plane distribution image thereof. 601 is the integration in FIG. 8, 602 is the integration in FIG. 9, 603 is the integration in FIG. 10, and 604 is the integration result in FIG. 11. In the in-plane distribution image 604, the brightness difference between the defect signal and the pattern signal is large. That is, it can be seen that the formula (3) is maximized. A defect having contrast anisotropically improved by horizontal polarization illumination is classified as an H defect. Similarly, a defect having contrast improved by vertical polarization illumination is called a V defect, and a defect having contrast that is not dependent on polarization is called an I defect. Defects generated in all pattern shapes are classified by a similar method to create the defect database 23.

According to the above procedure, the defect database 23 holds a record in which the combination of the defect classification and the polarization direction and wavelength (optical profile) at which image contrast of the defect is highest is described for each defect classification. In S703, the main console 16 lists the optical profiles described in the defect database 23, and acquires a low-magnification SEM image of the defect using each of the listed optical profiles. Accordingly, in S707 and S708, the defect can be detected on the SEM image using the optical profile j in which the contrast of the defect is enhanced. The defect detection method corresponds to aspect 1 of the principle of increasing the CNR.

### Embodiment 1: Summary

The charged-particle beam device 1 according to Embodiment 1 can identify a defect position by a local change in the signal intensity by selecting a light parameter whose LSPR characteristic greatly changes depending on the presence or absence of a defect. Accordingly, a high-performance defect inspection SEM device with improved defect identification and defect classification functions in a wide field of view can be provided. The throughput of defect detection can be improved by widening the field of view. Further, the defect can be automatically detected and classified by using the defect database 23 describing the polarization direction of the illumination light capable of enhancing the defect contrast.

### Embodiment 2

In Embodiment 2 of the invention, an operation example will be described in which a defect is inspected with high sensitivity by signal enhancement by LSPR due to a defect structure in a hot spot where a pattern is broken and a defect frequently occurs. A configuration of the charged-particle beam device 1 is similar to that in Embodiment 1.

FIG. 13 shows an inspection image of a hot spot where pattern breakage defects frequently occur. 701 denotes a high-resolution SEM image of a normal circuit pattern, and 702 denotes a high-resolution SEM image of a circuit pattern including a pattern breakage defect. The pattern breakage defect occurs in a portion surrounded by a circle in 702. Optically assisted SEM images when light satisfying the LSPR condition generated in the pattern breakage structure is incident are denoted by 703 and 704. The enhancement of the signal intensity in the pattern breakage structure means an increase in the numerator of the formula (3), that is, an increase in the CNR.

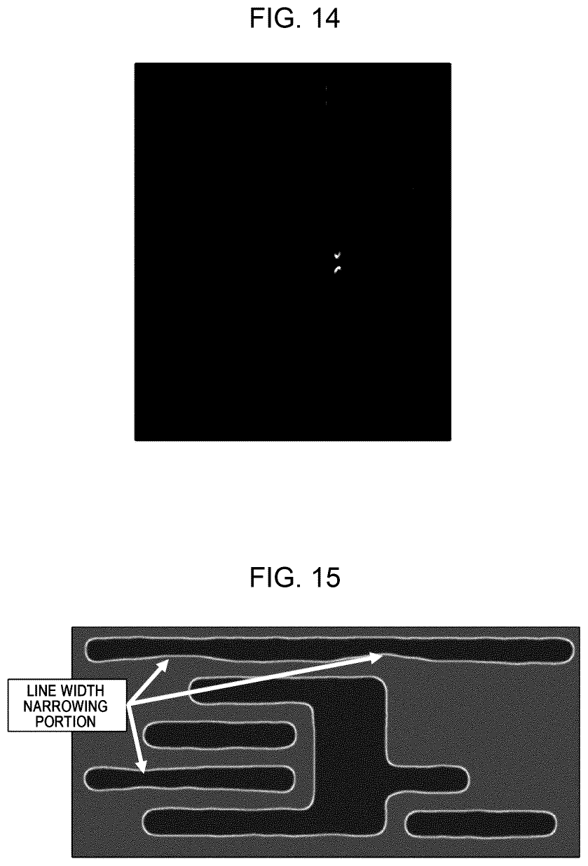

FIG. 14 shows that CNR can be increased by difference processing of the optically assisted SEM image. FIG. 14 shows a difference image between the optically assisted SEM image 703 of the normal pattern and the optically assisted SEM image 704 of the circuit pattern including the pattern breakage structure. It can be seen that the contrast between a signal of the pattern breakage structure and a background signal increases. This is because the background signal σ²_{struct} derived from the structure, which is the first term on the right side of the formula (4), has decreased. The CNR of a defect signal generated in a hot spot is increased as much as possible, and a high-sensitivity inspection can be performed. This defect detection method corresponds to the aspect 3 of the principle of increasing CNR. The main console 16 can detect the pattern breakage defect using the above principle in S707 and S708.

A position at which a pattern breakage defect occurs, a short-circuit direction, a short-circuit shape, and the like vary for each defect, and therefore, it is not always easy to classify the types of pattern breakage defects in advance and specify an optical profile suitable for each type. Therefore, a method using the difference image as shown in FIGS. 13 and 14 is useful. However, the pattern breakage defect tends to occur as a short-circuit defect in a portion where two normal patterns are arranged relatively close to each other with an interval therebetween. That is, in order to detect a pattern breakage defect, it is desirable to use an optical profile suitable for detecting the size and direction of the short-circuited part. Therefore, the defect database 23 preferably describes in advance an optical profile suitable for detecting a short-circuit defect according to the size, shape, pattern interval, and the like of the normal pattern described in the design pattern.

In the present embodiment, a pattern breakage defect can be detected with high sensitivity in a hot spot where a pattern breakage defect frequently occurs. As described in Embodiment 1, the inspection throughput is high, and therefore, the pattern breakage defect can be detected at a high speed.

### Embodiment 3

In Embodiment 3 of the invention, a description will be given of an optically assisted SEM device that inspects a dimensional abnormality from a signal intensity in a hot spot where a defect that cannot satisfy a desired dimensional range frequently occurs by using the fact that LSPR characteristics have pattern line width dependency.

FIG. 15 shows a high-resolution SEM image of a circuit pattern including a pattern line width narrowing portion. It can be seen that there are three pattern line width narrowing portions. The narrow portion referred to here is a portion in which the line width is smaller than that of other portions inside one linear pattern. Similarly, a portion where the line width is larger than that of other portions is also a line width abnormality defect.

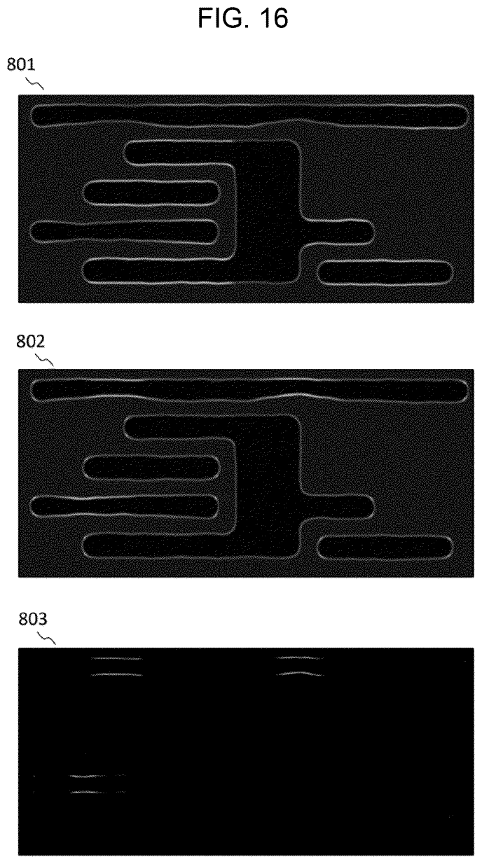

FIG. 16 shows an optically assisted SEM image of the pattern circuit in FIG. 15. Reference numeral 801 denotes an SEM image (see FIG. 3) when the incident wavelength λ>λth, and Reference numeral 802 denotes an SEM image when the incident wavelength λ<λth. In 801, a signal of a line width portion of a design median value is enhanced, and in 802, a signal of a narrow portion is enhanced. Reference numeral 803 denotes a difference image between the SEM image 802 and the SEM image 801. The narrow portion can be determined based on the signal intensity, and therefore, the line width abnormality can be inspected based on the signal intensity. Other line width abnormalities can also be inspected according to the same method. The main console 16 can detect the line width abnormality defect using the above principle in S707 and S708.

### MODIFICATIONS OF INVENTION

The invention is not limited to the above embodiments and includes various modifications. For example, the above embodiments are described in detail to facilitate understanding of the invention, and it is not necessary to include all the configurations described above. A part according to one embodiment can be replaced with a configuration according to another embodiment. A configuration according to another embodiment can be added to a configuration according to one embodiment. A part of a configuration according to each embodiment may be added to, deleted from, or replaced with a part of a configuration according to another embodiment.

In addition, in S707 and S708 of the above embodiment, the main console 16 may detect a defect by generating an observation image after bringing the spatial resolution as close as possible to the pattern pitch according to the principle described in (Aspect 2 of Principle of Increasing CNR: Spatial Resolution and Pattern Pitch).

In the above embodiments, the main console 16 may present an observation image of the sample 8 (which may or may not include a defect) on a user interface. For example, in the user interface of FIG. 6, when the SEM file name is double-clicked, the observation images exemplified in FIGS. 8 to 11, 13 and 14, 15 and 16, and the like may be presented.

In the above embodiments, the main console 16 and each functional unit of the main console 16 may be implemented by hardware such as a circuit device implementing functions of the main console 16 and each functional unit of the main console 16, or may be implemented by an arithmetic device such as a central processing unit (CPU) executing software implementing functions of the main console 16 and each functional unit of the main console 16. Alternatively, the main console 16 and each functional unit of the main console 16 may also be implemented by a computer including at least any one of these.

In the above embodiments, the review SEM has been described as an example of the charged-particle beam device 1, and the principle of the invention can also be applied to a case where the contrast of a defect is enhanced by light irradiation in other charged-particle beam devices.

### REFERENCE SIGNS LIST

1: charged-particle beam device
2: electron gun
5: detector
13: light source
14: light control unit
16: main console

1. A charged-particle beam device for emitting a charged particle beam to a sample, the device comprising:
a charged particle source configured to emit primary charged particles to the sample;
a light source configured to emit light to irradiate the sample;
a detector configured to detect secondary charged particles generated from the sample by emitting the primary charged particles to the sample;
a computer configured to generate an observation image of the sample using the secondary charged particles detected by the detector;
a light control unit configured to control a light parameter representing a physical property of the light; and
a database configured to describe combinations of a wavelength of the light and a polarization direction of the light, which enhance contrast of the observation image of a defect in the sample, wherein
the light control unit emits the light to the sample using at least one of the combinations,
the computer generates the observation image for each of the combinations used by the light control unit, and
the computer detects the defect using the observation image.

2. The charged-particle beam device according to claim 1, wherein
the computer generates the observation image at a first magnification when detecting the defect using the observation image,
the computer generates the observation image at a second magnification higher than the first magnification at a position of the defect detected using the observation image, and
the computer searches for the defect using the observation image generated at the first magnification when detecting the defect using the observation image, thereby detecting the defect in a field of view range wider than a field of view range after specifying the position of the defect.

3. The charged-particle beam device according to claim 1, wherein
the computer acquires design pattern data describing a design value of a shape pattern formed on the sample,
the computer acquires a defect list describing a list of types of the defects,
the computer acquires a correspondence relationship among the design value, the type, and a candidate of the combination,
the computer receives a designation input designating a detection target type among the types and the design value and specifies the candidate of the combination by referring to the correspondence relationship according to the designation input, and
the computer detects the defect using the specified candidate of the combination.

4. The charged-particle beam device according to claim 1, wherein
the database describes the combination for each type of the defect, and
the computer classifies the type of the defect based on the combination used in the light when the defect has been detected.

5. The charged-particle beam device according to claim 1, wherein
the computer acquires design pattern data describing a design value of a shape pattern formed on the sample, and
the computer generates the observation image to minimize a difference between a pattern pitch of the shape pattern described in the design pattern data and a spatial resolution of the observation image.

6. The charged-particle beam device according to claim 1, wherein
the computer generates the observation image of same portion for each of a first sample and a second sample having same shape pattern to generate a first observation image of the first sample and a second observation image of the second sample,
the computer generates a difference image between the first observation image and the second observation image, and
the computer detects the defect using the difference image.

7. The charged-particle beam device according to claim 1, wherein
the database describes
a first wavelength of the light configured to enhance the contrast when a size of a shape pattern formed on the sample is a first size, and
a second wavelength of the light configured to enhance the contrast when the size of the shape pattern formed on the sample is a second size,
the light control unit emits the light using each of the first wavelength and the second wavelength,
the computer generates a first observation image of the sample when the light is emitted using the first wavelength,
the computer generates a second observation image of the sample when the light is emitted using the second wavelength, and
the computer detects a size abnormality of the shape pattern as the defect by comparing the first observation image with the second observation image.

8. The charged-particle beam device according to claim 1, wherein
the light control unit emits the light using each of a first polarization direction and a second polarization direction,
the computer generates a first observation image of the sample when the light is emitted using the first polarization direction,
the computer generates a second observation image of the sample when the light is emitted using the second polarization direction, and
the computer detects, by comparing the first observation image with the second observation image, the defect having a characteristic of enhancing the contrast with respect to either the first polarization direction or the second polarization direction.

9. The charged-particle beam device according to claim 8, wherein
the sample has a shape pattern in which two or more holes are arranged at intervals, and
the computer detects the defect connecting the holes and detects a direction in which the defect extends between the holes, by comparing the first observation image with the second observation image.

10. The charged-particle beam device according to claim 6, wherein
the sample has two shape patterns arranged at an interval, and
the computer detects the defect using the difference image to detect the defect caused by a short circuit of the interval between the two shape patterns.

11. The charged-particle beam device according to claim 10, wherein
the database describes at least one of the wavelength or the polarization direction in which contrast of the defect caused by the short circuit of the interval is enhanced on the difference image, and
the light control unit enhances the defect caused by the short circuit of the interval on the difference image by emitting the light according to the wavelength or the polarization direction described in the database.

12. The charged-particle beam device according to claim 7, wherein
the sample has a linear pattern, and
the computer compares the first observation image with the second observation image to detect, as the defect, a portion of the linear pattern having a line width different from that of another portion.

13. The charged-particle beam device according to claim 1, wherein
the computer provides a user interface that presents at least any one of
the observation image,
an image of the defect included in the observation image, or
the combinations.
